(19) United States
(12) Patent Application Publication
(10) Pub. No.: US 2025/0255185 A1
(43) Pub. Date: Aug. 7, 2025

(54) APPARATUSES AND METHODS INVOLVING ELECTRICAL POWER GENERATION WITH RADIATIVE COOLING

(71) Applicant: The Board of Trustees of the Leland Stanford Junior University, Stanford, CA (US)

(72) Inventors: Shanhui Fan, Stanford, CA (US); Lingling Fan, Stanford, CA (US); Wei Li, Palo Alto, CA (US); Meir Orenstein, Haifa (IL); Weiliang Jin, Stanford, CA (US)

(21) Appl. No.: 19/088,809

(22) Filed: Mar. 24, 2025

Related U.S. Application Data
(63) Continuation of application No. 18/015,010, filed on Jan. 6, 2023, now abandoned.
(60) Provisional application No. 63/049,324, filed on Jul. 8, 2020.

(51) Int. Cl. H10N 10/17

(52) U.S. Cl. CPC H10N 10/17

(57) ABSTRACT

In certain examples, methods, apparatuses and semiconductor-related structures are directed to nighttime-like electrical power generation by use of a spectro-angular selective emitter as an optimal radiative cooler and a thermoelectric power generator (TEG) having a hot side and a cold side. The cold side may be coupled to the spectro-angular selective emitter which is directed to or facing an atmosphere characterized by an absence of solar light. Power may be generated via the TEG based on energy directed from the spectro-angular selective emitter and by controlling or limiting ability of the spectro-angular selective emitter to absorb heat power at frequencies and/or angles where emission of the atmosphere is dominant.

### FEDERALLY-SPONSORED RESEARCH AND DEVELOPMENT

This invention was made with Government support under contract DE-FG02-07ER46426 awarded by the Department of Energy. The Government has certain rights in the invention.

### BACKGROUND

Aspects of the present disclosure are generally directed to methods and apparatuses (e.g., systems and devices) in which electrical power is generated or harvested such as via radiative cooling, passively, and/or in the absence of solar light such as at nighttime. Many commercially-available systems attempting to generate electrical power and involving such aspects are challenged and/or result in less-than-ideal or less-than available efficiency realizations. Other (non-limiting) examples where improvement to such methods and apparatuses is in the field of generation of solar power when solar cells are not working.

Efficiencies and/or availability of materials associated with such methods and apparatuses, and other matters related to radiative cooling, have presented challenges in the field of electrical power generation.

### SUMMARY OF VARIOUS ASPECTS AND EXAMPLES

Various examples/embodiments presented by the present disclosure are directed to issues such as those addressed above and/or others which may become apparent from the following disclosure. For example, some of these disclosed aspects are directed to methods and devices involving “nighttime” thermal power generation. In some instances, such power generation may be characterized by way of an electrical power density, and/or by use of commercially available technology. It will be appreciated however, that such characterizations and uses are not required.

In particular examples, the present disclosure is directed to a method/system involving nighttime thermoelectric power generation (sometimes referred to generally as “nighttime” or passive power generation and as may be characterized by “power density”) as may be realized in the absence of solar light such as at nighttime. In various examples, such nighttime thermoelectric power is generated at relatively high levels (e.g., greater than 1.5 W/m², 2 W/m² or 6 W/m², and in ranges encompassing these exemplary levels) based on at least one of or a combination of multiple ones of the following: comprehensive optimization/improvement of radiative coolers, environmental convection, and thermoelectric figure of merit.

In certain specific example, a method and/or a semiconductor-type device involves generation of electrical power by use of an optimal radiative cooler or a spectro-angular selective emitter (characterized by its ability to control or limit the ability to absorb heat power at frequencies and/or angles where emission of the atmosphere is dominant) and by use of a thermoelectric power generator (TEG). The TEG has a hot side and a cold side, with the cold side coupled to the spectro-angular selective emitter which is directed to or facing an atmosphere characterized by an absence of solar light. Power may be generated via the TEG based on energy directed from the spectro-angular selective emitter and by controlling or limiting ability of the spectro-angular selective emitter to absorb heat power at frequencies and/or angles where emission of the atmosphere is dominant.

In certain more specific examples which may also build on the above-discussed aspects, such methods, devices and apparatus are directed to the spectro-angular selective emitter as part of radiative cooler (e.g., multi-layered materials optimized for the apparatus) and the power being generated is at a level that exceeds 1.5 W/m². This is due at least in part to: engineered or optimized environmental convection associated with the TEG and the spectro-angular selective emitter; a thermoelectric figure of merit set to improve nighttime power density generation and/or an upper limit of nighttime power density; and/or an area ratio between the TEG and the radiative cooler engineered or optimized to facilitate said generating power at a level that exceeds 1.5 W/m².

In further specific examples which may also build on the above-discussed aspects, an integrated device or system has a base structure (e.g., housing and/or foundation supporting components of the device or system) with an infrared window between the atmosphere and the spectro-angular selective emitter and with a vacuum chamber around the spectro-angular selective emitter which may be implemented as or with multiple dielectric material layers. At the hot side of the TEG, a heat sink is thermally coupled to the set of multiple dielectric material layers and/or to the spectro-angular selective emitter.

In the above and other particular examples, an apparatus and/or method involves use of optimized radiative cooler with spectro-angular selectivity being configured to yield high-performance power generation (e.g., as might be useful in various environmental and thermoelectric device conditions), and/or use of a spectro-angular-selective emitter.

In other more specific examples, aspects of the present disclosure are directed to and may be used as a systematic optimization of nighttime thermoelectric power generation systems utilizing radiative cooling. Surprising results have been realized through various non-limiting experimental and/or proof-of-concept examples.

In more specific examples, such methodology and/or apparatuses may be used as part of a low-cost, off-grid, passive system that can generate light during nighttime. Further, in addition to lighting, a modular energy source adapted to such methodology, circuitry and/or systems can benefit a large variety of off-grid sensors (e.g., agriculture, environmental, security, digital-communications systems and other types of systems).

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure, in which:

FIG. 1A is an electrical-power-generator apparatus, according to certain exemplary aspects/embodiments of the present disclosure;

FIG. 1B is a schematic setup of a thermoelectric power generator (TEG) utilizing radiative cooling in a manner consistent with certain exemplary aspects/embodiments of the present disclosure;

FIG. 2 is another electrical-power-generator apparatus, according to certain exemplary aspects/embodiments of the present disclosure;

FIGS. 3A, 3B, 3C, 3D and 3E diagrams relate to an experimental example embodiment, according to certain exemplary aspects/embodiments of the present disclosure, involving an electrical-power-generator apparatus, with:

FIGS. 3A and 3B respectively showing ideal and actual emissivity performance aspects,

FIG. 3C showing a certain example multi-layer material structure for an emitter used in connection with FIG. 3B,

FIG. 3D showing output power density relating to an optimal emitter, a multi-layer emitter as in FIG. 3B, and a blackbody emitter, and

FIG. 3E showing temperature differences relating to the above-noted optimal, multi-layer and blackbody emitters;

FIGS. 4A and 4B are respectively an alternative electrical-power-generator apparatus and a related performance graph, according to certain exemplary aspects/embodiments of the present disclosure; and

FIG. 5 is yet is another electrical-power-generator apparatus, according to certain exemplary aspects/embodiments of the present disclosure.

While various aspects illustrated herein by way of example in the drawings and to be described in more detail, these illustrations do not disclose each particular example embodiments describe herein. In addition, the term “example” as used throughout this application is only by way of illustration, and not limitation.

### DETAILED DESCRIPTION

Aspects of the present disclosure are believed to be applicable to a variety of different types of apparatuses, systems and methods involving generation of electrical power in the absence of solar light, for example, passively and/or at nighttime (sometimes referred to generally as “nighttime” generation of electrical power). While the following discussion (including the Appendices of the underlying U.S. provisional application) may refer to specific implementations for generation of electrical power in the absence of solar light via certain apparatuses or optimization methods, such discussion is for providing merely an exemplary context to help explain such aspects, and the present disclosure is not necessarily so limited. See also same Equations 1 through 6 and related parameters and discussion in Appendix A of U.S. Provisional cited herein.

Accordingly, in the following description various specific details are set forth to describe specific examples presented herein. It should be apparent to one skilled in the art, however, that one or more other examples and/or variations of these examples may be practiced without all the specific details given below. In other instances, well-known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Exemplary aspects and embodiments of the present disclosure are related to a system and/or a method involving relatively high-level thermoelectric power generation and which may be characterized via a parameter referred to as “nighttime power density” (e.g., in the absence of solar light such as at nighttime). In certain non-limiting specific embodiments, by use of thermoelectric power generator (TEG) and a spectro-angular selective emitter for radiative cooling, such high levels in various example instances have been greater than 1.5 W/m², greater than 2 W/m² and greater than 6 W/m². Each of these levels provide significant improvement by way of or based on optimization of a radiative cooling portion of the power-generator apparatus, environmental convection and/or thermoelectric figure of merit.

In yet other examples, one or more of the above features (e.g., spectro-angular-selective emitter, improved of radiative coolers, environmental convection and/or thermoelectric figure of merit) are used to improve nighttime power density generation and/or an upper limit of nighttime power density. In yet further-related examples, one or more of such features may involve optimization in a system with configured/optimized emitters and/or at different thermal convection conditions,

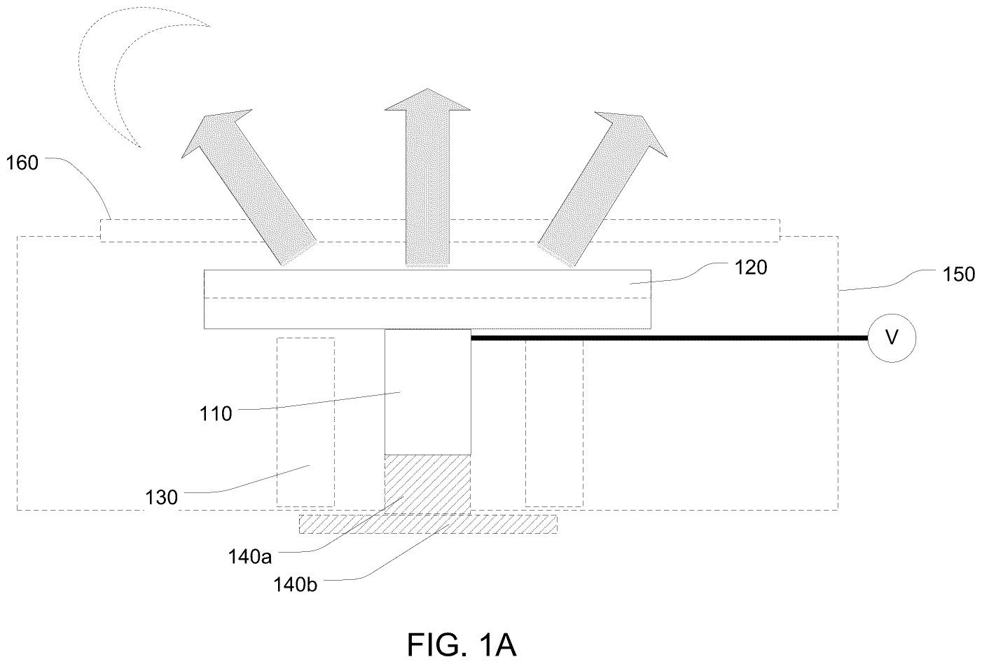

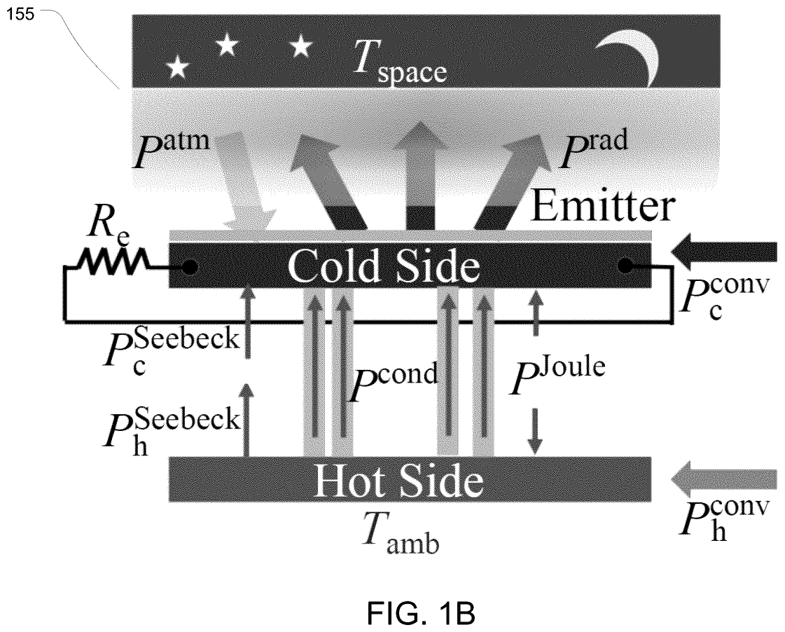

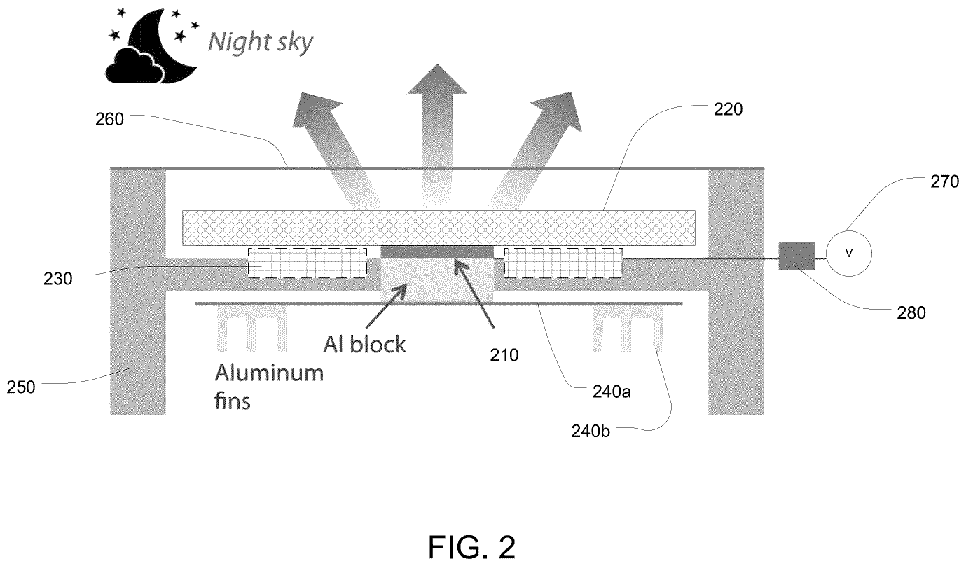

In certain specific examples according to the present disclosure, embodiments such as described above are directed to a type of system as shown in FIG. 1A (and similarly in FIG. 2) where the system has a TEG 110 configured to work in conjunction with an optimized radiative cooling mechanism involving a spectro-angular-selective emitter 120, the latter of which is configured to yield high-performance power generation (e.g., as might be useful in various environmental and thermoelectric device conditions). In this particular example shown in FIG. 1A, the apparatus may as an option have the emitter 120 optimized by including one or more materials in the emitter designed specifically to maximize radiative cooling, and may also have other aspects to improve or optimize environmental convection and/or thermoelectric figure of merit. In FIG. 1A such aspects are shown to include a radiation shield structure 130 adjacent to or surrounding the TEG 110 (e.g., between its upper cold side and its lower hot side), heat sinking structure such as a thermal conductor 140a and heat-sink fins 140b designed with sufficient surface area to dissipate heat directed from the TEG 110. A housing 150, with an infrared window 160, may be used to contain the device or system components for providing the power generated by the TEG 110 at an electrical terminal as shown by way of the “V” to represent a voltage source to be used for an external circuit (e.g., light-emitting diode, logic circuitry, controller, day-versus-night sensor circuitry). Further, the housing 150 may also be used to facilitate providing the emitter 120 and any other optimization components of the radiative cooling structure (e.g., the shield(s) 130) in a vacuum chamber.

The operation of this type of system, consistent with FIG. 1A and other examples herein, may be best understood by analyzing a thermodynamic model of nighttime thermoelectric power generator and as schematically shown in FIG. 1B. The cold side of the TEG is integrated at temperature T_{c} with a radiative cooler, whose radiative properties are described by the emissivity ε(λ, θ) at wavelength and incident angle from the normal direction θ. The cold side is exposed to the clear night sky and subject to atmospheric irradiance that depends on the ambient temperature T_{amb}. The temperatures of the cold and hot sides of the TEG, T_{c} and Tₕ, can be obtained by solving the steady-state power balance of the two sides as in the following equations (as reproduced from Appendix A of U.S. Provisional Application Ser. No. 63/049,324 filed on Jul. 8, 2020 (STFD.420P1), to which priority is claimed):

$${P}^{ra d} - {P}^{a tm} - {P}^{cond} - {P}_{c}^{conv} - {P}^{Joule} - {P}_{c}^{Seebeck} = 0 \qquad ( Eq . 1 )$$

$${P}^{cond} - {P}_{h}^{conv} - {P}^{Joule} + {P}_{h}^{Seebeck} = 0 \qquad ( Eq . 2 )$$

In this analysis, p^{rad} is the power radiated out by the radiative cooler, p^{atm} is the power absorbed in the cold side stemming from the atmosphere radiation, and each of p^{rad} and p^{atm} is a function of A_{c} which is the cold-side surface area of the structure illustrated in FIG. 1B. The analysis also takes into account the angle-dependent spectral emissivity of the atmosphere (which is a function of the atmospheric transmittance in the zenith direction). Also in the above equations, P^{cond} (=Tₕ T_{c}/R_{TE}) represents the internal parasitic heat transfer from the hot to the cold side due to conduction with R_{TE} being the thermal resistance of the TEG structure, and P^{conv} (=A_{c} h_{c} (T_{amb}−T_{c}) and P^{conv}=Aₕ hₕ (T_{amb}−Tₕ) are the heat transfer from the ambient to the cold and hot side respectively due to air convection, where Aₕ is the hot-side surface area of the structure, and hₕ and h_{c} are the air convective heat transfer coefficients due to the contact of air adjacent to the hot side of TEG and the radiative cooler, respectively.

Additionally, there is heat power related to the Joule heating and Seebeck effect in Equations 1 and 2. P^{Joule} (=N/2 I² Rₙₚ) is the heat provided to either the hot and cold side due to Joule heating of the internal resistance. With respect to the following standard treatment for simplicity, it is assumed that such heat is provided equally to the hot and the cold sides. The current is then a function of: the number of thermocouples in the TEG; the Seebeck coefficient of a single junction; and the external and single thermocouple's internal electrical resistances.

Further as in Equations 1-2 and FIG. 1B: Pₕ^{Seebeck} (=NSₙₚ Tₕ) and P_{c}^{Seebeck} (which is equal to NSₙₚ T_{c}I) are the heat outflow and inflow of the hot and cold side due to the Seebeck effect, respectively. The hot side is assumed to have a very low emissivity, thus the radiated power of the hot side is negligible. This assumption is widely applied in radiative cooling devices and is applicable here as well. In a realization of such an example embodiment, the hot side is immersed in air and separated from other thermal reservoirs such as the ground or roof, so the heat convection from air is the sole power source of the system. Given these assumptions, by mathematically combining Eq. 2 with Eq. 1, both T_{c} and Tₕ can be solved.

To maximize electric power generation for a given temperature difference (Tₕ−T_{c}), the load-matching condition may be applied where Rₑ=NRₙₚ. The maximum power density pₘₐₓ is obtained directly from Equations 1 and 2 as the difference between the net external power delivered to the hot side and leaving the cold side as expressed in Eq. 3:

$$p max = {{NS}_{np}^{2} ( Th - Tc )}^{2} / 4 {R}_{np} {A}_{c} \qquad ( Eq . 3 )$$

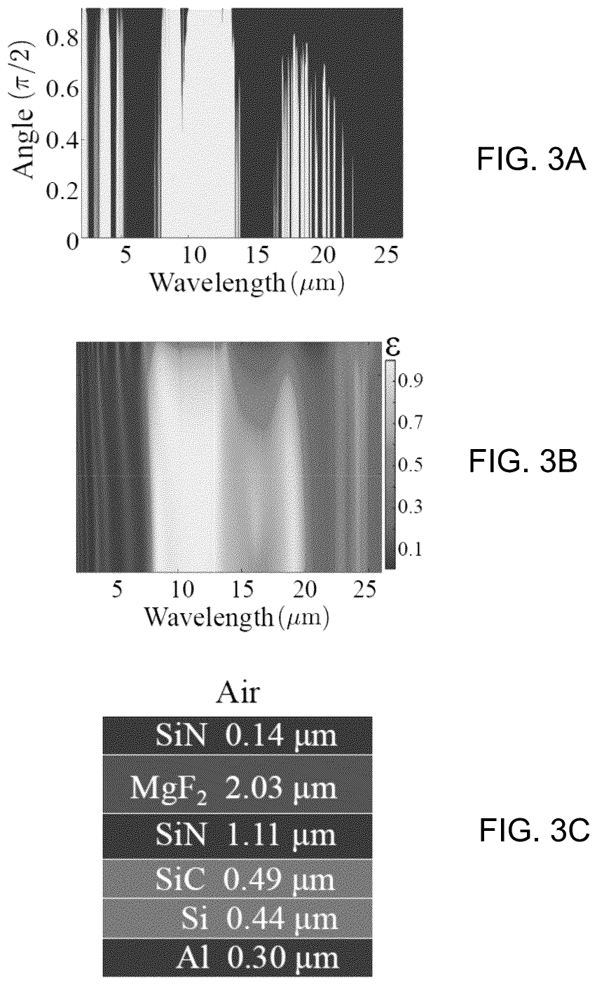

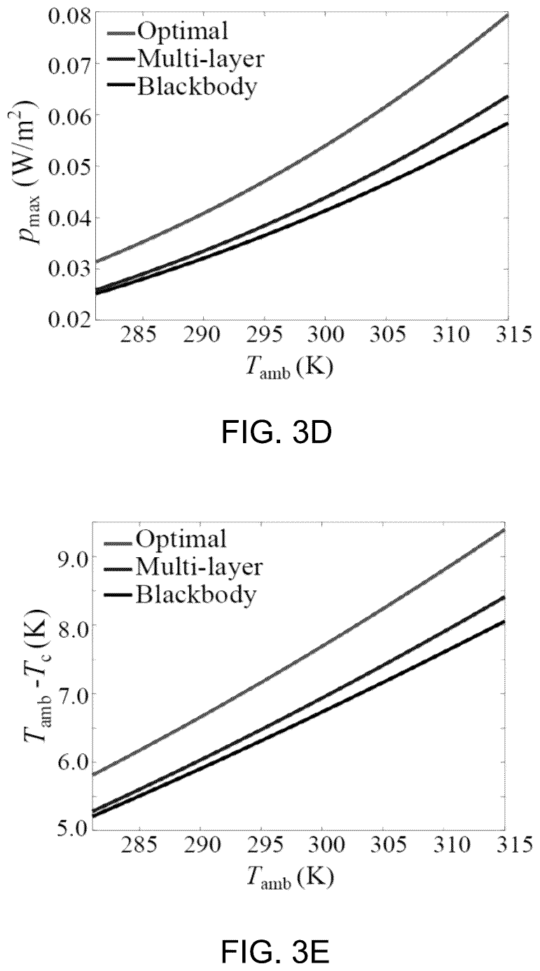

According to a specific example of the present disclosure (e.g., a proof-of-concept experiment with ablackbody emitter (as previously reported in A. P. Raman, W. Li, and S. Fan, “Generating light from darkness,” Joule 3, 2679-2686 (2019)), the power generation system parameters were: T_{amb} ˜281 K, hₕ=10 W/(m²K), h_{c} ˜7 W/(m²K), R_{TE} equals 2.5 K/W, A_{c}=Aₕ=0.01π m², N=127, Sₙₚ=210.769 μV/K, Rₙₚ=0.007Ω. The single thermocouple effective area is A_{TC}=A_{TE}/N, where the TEG area A_{TE} is 30×30 mm² from Marlow TG12-4-01LS used in the above-cited article entitled, “Generating light from darkness.” The temperature difference obtained in this experiment was Tₕ−T_{c}=1.98 K, and the generated electrical power density pₘₐₓ=0.025 W/m². Using this modeling, this experiment reproduced such results consistently, as shown herein in connection with FIGS. 3D and 3E. As demonstrated in discussion herein and in accordance with aspects of the present disclosure, this power generation performance may be improved significantly by optimally engineering one or a combination of the following aspects: the radiative cooler emissivity spectra, the area ratio between the TEG and the radiative cooler, the thermoelectric figure of merit, and/or environmental convection conditions. In certain example embodiments and applications, optimally engineering each of these above aspects has been found to be highly advantageous.

FIG. 2 is presented to show, in part as with FIG. 1A discussed above, another of a number of different exemplary systems according to the present disclosure. The system of FIG. 2 may be engineered for excellent power generation performance by taking advantage of some of one or a combination of the above-discussed aspects. FIG. 2 differs from FIG. 1A with regards to, for example, a differently-structured and/or type of TEG 210, (e.g., with different surface areas such as cold-side, hot-side and/or thickness dimensions as in FIG. 1A), and with shielding and heat sinking based on different types, shapes and sizes which are chosen or engineered to compensate accordingly. More specifically, the example system of FIG. 2 is engineering with multiple ones of the above aspects working in conjunction with an optimized radiative cooling mechanism involving a spectro-angular-selective emitter 220 for yielding high-performance power generation. The system (or apparatus) of FIG. 2 may have as an option the emitter 220 optimized by including one or more materials in the emitter designed specifically to maximize radiative cooling, and may also have other aspects to improve or optimize environmental convection and/or thermoelectric figure of merit. In FIG. 2, such aspects include a horizontally-elongated radiation shield structure 230 adjacent to or surrounding the relatively short TEG 210, and a heat-sinking structure including thermal conductor (below the TEG 210), an aluminum-based structure having an aluminum block thermally integrated with a fin-based 240b. As with the design in FIG. 1A, the system of FIG. 2 is engineered to have sufficient (or optimized) heat-sink surface area to dissipate heat directed from the TEG 210. Structure (or base) depicted as 250 may be part of a housing to support the shielding at 230 and the conductor running from TEG 210 to an optional boost converter 280 from which the generated power may be accessed. The structure 250 may have a wind shield or window 260 over the top portion to protect the system from damage. Other aspects are similarly depicted as in FIG. 1A (e.g., “V” represents a voltage source 270 to be used for supplying power to an external circuit). While not labeled in FIG. 2, the wind shield or window 260 may be used to seal the area including the emitter 220 and related engineered/optimizing components of the radiative cooling structure in a vacuum chamber.

Maximization of the power density generation pₘₐₓ of the TEG, the temperature of its cold side should be decreased as much as possible as evidenced by Eq. 3, which makes the optimal radiative cooler an important element in the system. The power density balance of the cooler can be written as expressed in

$$Δ pr ( Tc ) = Δ ppar ( Tc ) , \qquad ( Eq . 4 )$$

where Δpᵣ(T_{c})=∫dΩ cos θ∫₀^{∞}dλ[I_{BB} (T_{c}, λ)−I_{BB} (T_{amb}, λ)εₐₜₘ(λ, θ)]ϵ(λ, θ) is the net radiative power density from the cold side and appar (T_{c}) is the parasitic heat transfer density into the cold side and which may be expressed as being =h_{c}(T_{amb}−T_{c})+1/A_{c}[(Tₕ−T_{c})/R_{TE})+Z(Tₕ−T_{c})²/8R_{TE}+Z(Tₕ−T_{c})T_{c}/2R_{TE}]. The T_{c} solution is uniquely determined by the intersection of the two monotonous functions Δpᵣ(T_{c}) and Δ par(T_{c}). This derivation highlights two important factors that influence the performance of the power generation: the control of the cold side emissivity ϵ(λ, θ), as well as various parameters related to the TEG setup which represents the effective heat transfer coefficient of all parasitic heat transfer and controls the cold side temperature.

Turning now to the emissivity design, for a given T_{c}, the optimal emissivity spectrum ϵ(λ, θ) should maximize the cooling power by filtering out the negative contribution of the integral in Δ pᵣ. This may be achieved by assigning ϵ(λ, θ)=1 when the amount of power radiated out from the cooler is larger than the power it absorbs from the atmosphere radiation and otherwise ϵ(λ, θ)=0. The optimal emissivity should conform with:

$$ϵ ( λ , θ ) = □ [ {I}_{BB} ( Tc , λ ) - {ε}_{a tm} ( λ , θ ) {I}_{BB} ( Tamb , λ ) ] , \qquad ( Eq . 5 )$$

where □ is the unit step function, and T_{c} is solved self-consistently from Equations 1, 2 and 5. The spectral selectivity of the optimal cooler gives strong emission at frequencies where the atmospheric absorption (in the range of 8-13 μm) and the ozone layer reflection (9.5 μm) are relatively smaller. The angular selectivity of the emitter also prevents emissions at large incident angular ranges where the sky is mostly opaque and the downward sky radiation is intensive. The optimal emissivity spectrum ϵ(λ, θ) is shown in FIG. 3A at nighttime ambient temperature 300 K and other conditions the same as in the above-referenced article entitled, “Generating light from darkness.” This optimal emissivity cools down the cold side to T_{c}=292.3 K as determined by Equations 1, 2 and 5 and results in a power generation of 0.054 W/m², higher compared to 0.041 W/m² for a blackbody emitter under the same conditions.

### More-Detailed and/or Experimental Embodiments and/or Applications

FIGS. 3A-3E are presented to illustrate an exemplary nighttime power generator with selective thermal emitter for improved thermoelectric power generation in connection with more-detailed and/or experimental embodiments. FIG. 3A shows the ideal emissivity (Eq. 5 above) for optimal thermoelectric power generation at ambient temperature of 300 K, cooling down the emitter to T_{c}=292.3 K. FIG. 3B shows emissivity of the optimized multi-layer at ambient temperature of 300 K, cooling down the emitter to T_{c}=293.1 K. FIG. 3C shows one particular example of a set of multi-layers with each layer depicted to show a certain material composition and thickness to make up a multi-layer structure corresponding to the spectro-angular selectivity depicted for an emitter in connection with the performance illustration of FIG. 3B. Using the same orientation as in FIGS. 1A and 2 and from top to bottom, six layers are depicted in FIG. 3C as follows: SiN (0.14 microns), MgF₂ (2.03 microns), SiN (1.11 microns), SiC (0.49 microns), Si (0.44 microns) and Al (0.30 microns). FIG. 3D shows output power density pₘₐₓ of the above three emitters (Optimal, Multi-layer as in FIG. 3B, and Blackbody) at different ambient temperatures, and FIG. 3E shows temperature difference between the radiative cooler and ambient for the same three emitters. The other parameters of the TEG system are assumed to be the same as in the above-cited article entitled, “Generating light from darkness.”

More specifically, to implement an approximated optimized structure of a radiative cooler for high-performance electrical power generation, an improved or optimized multi-layer emitter may be used. To find the multi-layer structure for high-performance electrical power generation, a broadband optimization may be performed using known methods, with the radiative power density Δpᵣ as the merit function with T_{c}=292.3 K which is the temperature of the aforementioned optimal emitter. To achieve maximal power generation with a five-layer structure, a diverse set of materials may be employed so that the multi-layer structure can have an emissivity that approximately matches the optimal emissivity spectrum in FIG. 3A, taking into account fabrication feasibility. As an example superstrate, air is chosen, and the structure is placed on top of 300 nm of Al attached to the cold side of the TEG. A selection is made from the following ten common dielectric materials: Al₂O₃, HfO₂, MgF₂, SiC, SiN, SiO₂, TiO₂, Ta₂O₅, Si, Si₃N₄. The thick Al is impermeable to thermal radiation, thus the emissivity spectrum is

$$ϵ ( λ , θ ) = 1 - R ( λ , θ ) R ( λ , θ ) = 1 / 2 ( {R}_{s} ( λ , θ ) + {R}_{p} ( λ , θ ) ) is R ( λ , θ ) = \frac{1}{2} ( {R}_{s} ( λ , θ ) + {R}_{p} ( λ , θ ) )$$

and p polarized light, both of which is calculated by applying the analytical surface impedance method on a multi-layer structure as is known (see, e.g., H. A. Haus, Waves and Fields in Optoelectronics (Prentice Hall: Englewood Cliffs, NJ, 1983). Using the emissivity, the net radiative cooling power density Δpᵣ is calculated to evaluate the electrical power generation for the multi-layer device. In FIG. 3B, the emissivity spectrum of the calculated multi-layer structure is plotted, which demonstrates the selectivity on wavelength and incident angle that is favorable for thermoelectric power generation. The emissivity spectrum of the designed emitter approximates that of the theoretically optimal spectrum specified in FIG. 3A. The material composition and thickness constituents of the optimized emitter are shown in FIG. 3C.

To assess the power generation performance of this device, in FIG. 3D, the electrical power density of the optimal emitter described by Eq. 5, the optimized multi-layer emitter shown in FIG. 3C is compared with the blackbody device as in the above article “Generating light from darkness” under the same environmental and TEG conditions (e.g.,) for a range of ambient temperatures. Hence, at all temperatures, the above-described optimized multi-layer structure generates higher electrical power than the blackbody emitter. Nevertheless, the optimized multi-layer structure is outperformed by the optimal emitter shown in Eq. 5 which leaves space for even better emitter designs. Next, the working principle of the optimal emitter are explored, by presenting in FIG. 3E the temperature reduction of the cooler from the ambient. This verifies that, at all ambient temperatures, the optimal emitter lowers the cooler temperature further than the multi-layer and blackbody emitter. In other embodiments and aspects building on the above-discussed embodiments and aspects, adjoint optimization methodology may be implemented with diverse geometrical and material combinations, an emissivity design closer to the ideal goal of Eq. 5 may be achieved and consequently improve the power generation performance.

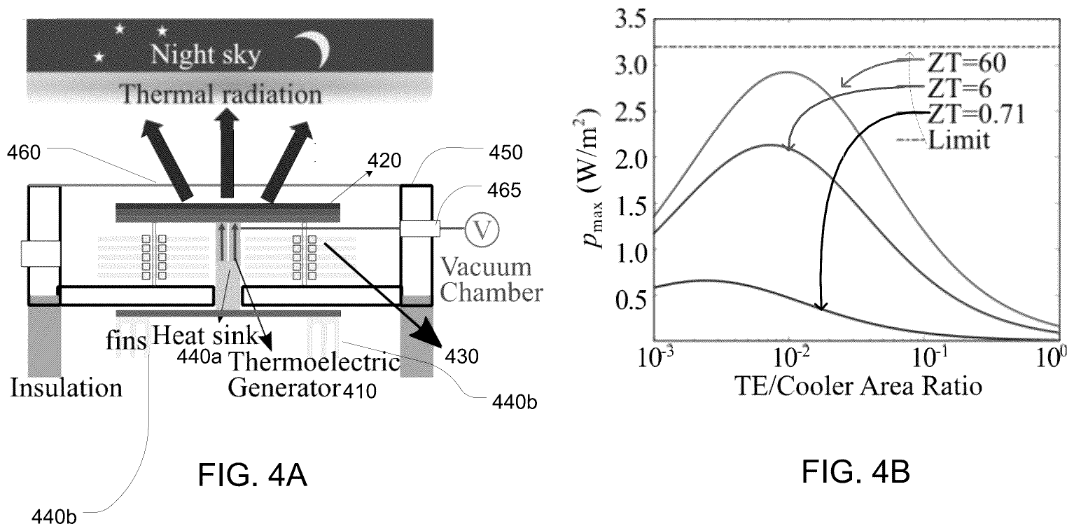

FIG. 4A shows another alternative system according to the present disclosure as a more-detailed and/or experimental embodiment having certain of the above-discussed optimization aspects disclosed in connection with each of FIGS. 1A, 2 and with the multi-layered structure as in FIG. 3C. The system of FIG. 4A corresponds to a feasible nighttime thermoelectric generator design that optimally generates 2.2 W/m² power density. As in FIGS. 1A and 2, the system of FIG. 4A has a TEG 410, a spectro-angular-selective emitter 420 acting as a radiative cooler and optimized by including multiple materials layers to maximize cooling, a radiation shield structure 430 adjacent to or surrounding the TEG 410, a heat sinking thermal conductor 440a and heat-sink fins 440b, a housing or support base 450, an infrared window 460, an electrical terminal 465 where the “V” represents a voltage source to be used for an external circuit, and the housing or support base 450 configured as part of a seal to provide a vacuum chamber around the emitter 420 and other components of the radiative cooling structure such as the shield(s) structure 430.

More specifically and according to another example aspect consistent with the other discussed aspects herein, optimization may be enabled by an affordable TEG having a thermal figure of merit (ZT)=6 and this may be compared with a more robust/futuristic TEG with a ZT=60 TEG (e.g., respectively described in References 37 and 38 of the above-referenced U.S. Provisional application, at Appendix A) and experimentally implemented ZT=0.71 TEG as in the article, “Generating light from darkness.” Here, ZT=NSₙₚ²R_{TE}T_{amb}/Rₙₚ, with ZT corresponding to the thermoelectric figure of merit at ambient temperature of 300 K. The system is enclosed by engineered thermal convection conditions: the vacuum cold-side environment can achieve negligible parasitic heating by air convection with h_{c}=10⁻³ W/(m²K), and the heat sink attached to the hot side of the TEG can increase the effective area for convection by a factor of 10 for still air convection, to yield effectively hₕ=10² W/(m²K). Furthermore, radiation shields and isolation pegs are used to reduce the radiation and conduction loss through the backside of the emitter.

FIG. 4B shows the output power density pₘₐₓ as a function of thermoelectric power density to radiative cooler area ratio for various thermoelectric figure-of-merit values, as well as the limit determined by half of the Carnot engine extracted power density, with h_{c}=10⁻³ W/(m²K) and hₕ=10² W/(m²K) at the ambient temperature of 300 K. To optimize the number of thermocouples in a rooftop application setting, where the system footprint area is assumed to be A_{c}=Aₕ=1 m², the thermoelectric power density pₘₐₓ may be studied as a function of the area ratio of the TEG to the radiative cooler A_{TE} A_{c} in FIG. 4B. The power density may be calculated as the generated power divided by this footprint area, and the convection coefficients of the hot and cold sides may be chosen to be the same as in FIG. 4A. Each of the emitters are designed to be optimal according to Eq. 5. For all of the three emitters, the output power density pₘₐₓ peaks at a respective A_{TE}/A_{c} area ratio. For the experimental ZT=0.71 case (see above article entitled, “Generating light from darkness”), the optimal output power density pₘₐₓ is 0.67 W/m² when the TEG consists of 339 thermocouples and corresponding area ratio A_{TE}/A_{c} is 0.0024. For the available ZT=6 case (above reference as #37), the optimal output power density pₘₐₓ is 2.2 W/m² obtained with 1001 thermocouples and corresponding area ratio A_{TE}/A_{c} is 0.007. For the futuristic ZT=60 case (above reference as #38), the optimal output power density pₘₐₓ is 2.92 W/m² with 1351 thermocouples and corresponding area ratio A_{TE}/A_{c} of 0.0096. For all three cases the maximum power density is achieved with the TEG area less than one percent of the radiative cooler area. For this observation, with the TEG being the most expensive part of the system, the upper bound of the thermoelectric power density generation on the load resistor is half of that obtained by an ideal Carnot engine (see discussion herein infra). According to the present disclosure, the experimental results for a technically achievable design are close to this Carnot limit of 3.2 W/m², denoted by a dashed line in FIG. 4B. Also, it is noted that producing 2.2 W/m² at night from an environmental source outperforms thermal energy harvesting from human body, as well as energy from radio frequency, and is comparable with other small-scale ambient energy harvesting techniques such as wind.

In addition to an important role the optimal emitter may play, a detailed study of the system parameters may be performed including convection coefficients, thermoelectric figure of merit and TEG/radiative cooler area ratio. Other aspects which may be considered are the TEG with ZT=6 of FIG. 4B at ambient temperature T_{amb}=300 K integrated with radiative cooler with the optimized emitter as a baseline, and values of each single parameter scanned and leaving the other parameters unchanged. A red dashed line marks the value of each specific parameter used in the experiment of the above-referenced entitled, “Generating light from darkness”: hₕ=10 W/m²/K, h_{c}=7 W/m²/K, ZT=0.71, and A_{TE}/A_{c}=0.0286.

As can be shown, the power density pₘₐₓ increases rapidly as a function of the hot-side effective convection coefficient, hₕ. At hₕ=10 W/(m²K), the power density is 1.909 W/m², which is a fairly good result for still air without assisting structure. It can be asymptotically improved to 2.2 W/m² for hₕ near 100 W/(m²K) by a properly designed heat sink or strong wind. Conversely, it can be shown that the power density pₘₐₓ decreases drastically as a function of the cold-side convection coefficient, h_{c}. At h_{c}=7 W/(m²K), the generated power density is only 0.1938 W/m², and asymptotically approaches 2.2 W/m² for h_{c} near 0.001 W/(m²K). This is a manifestation of the advantage of a vacuum enclosure, or special locations such as deserts as discussed by R. T. Bailey, J. W. Mitchell, and W. A. Beckman, “Convective Heat Transfer From a Desert Surface,” J. Heat Transf 97, 104-109 (1975), for achieving the desired power density.

As discussed above, the thermoelectric figure of merit ZT has a significant influence on electrical power generation. Higher ZT amounts to reduced electrical resistance and/or increased thermal resistance of the TEG, the first enhances the output current and the latter reduces the parasitic heating of the cold side. The power density pₘₐₓ increases rapidly as a function of ZT value. Power densities in the range of Watts/m² can be obtained with existing TEG technology as discussed previously, and new materials with corresponding and improved attributes (e.g., even higher ZT which operate at a temperature range near ambient temperature) may also be obtained.

The power density pₘₐₓ as a function of the area ratio of the TEG to the radiative cooler A_{TE} A_{c} for three types of emitters (Optimal, Multi-layer and Blackbody) may be considered. For all of the three, the output power density pₘₐₓ follows a similar trend as in FIG. 4B. At the area ratio 0.0286 employed in the experimental set up of the article entitled “Generating light from darkness”, an optimal emitter power density of 1.5529 W/m² may be achieved, while the multilayer emitter achieves 1.1169 W/m² and the blackbody emitter 0.8676 W/m². For the multi-layer emitter, the maximum output power density pₘₐₓ is 1.2144 W/m² when A_{TE} A_{c} is 0.0156, and the blackbody emitter generates the maximal output power density pₘₐₓ of 0.87 W/m² when A_{TE} A_{c} is 0.0252. The very low TEG area compared to the system footprint deserves additional consideration. Referring again to Eq. 3, the power density may appear to scale linearly with the TEG area (or the number of thermocouples, assuming the area of the thermocouple is fixed), for a given temperature gradient. However, the temperature gradient itself is reduced by increasing the TEG area, since more heat is pumped to the cold side and the related cooling resources are limited. The voltage of the TEG, which is proportional to N(Tₕ−T_{c}), increases but only as a sublinear function of N, while the current which is proportional to (Tₕ−T_{c}) decreases monotonically with N. The resulting optimal point is thus obtained for a relatively small A_{TE}/A_{c} ratio.

It is important to know the maximal achievable power density from the ambient air during nighttime. In an exemplary embodiment, a roof top area of 1 m² with A_{c}=Aₕ=1 m² is contemplated. In such an embodiment, the theoretical analysis is therefore based on replacing the aforementioned TEG model with a Carnot engine that works between the heat source and sink. Here, consideration is given to a practical atmosphere whose emissivity spectrum is the same as used in the TEG study of previous sections and the radiative cooler emitter is with an emissivity spectrum ϵ(λ, θ) given by Eq. 5. Therefore, the exemplary aspects and embodiments of the present disclosure are a departure from previous understandings on the limits for outgoing thermal radiation with idealized atmosphere or without atmosphere (as discussed in References 16, 17 and 46 as cited in the above-noted U.S. Provisional). In steady state and assuming the net heat flux of the cool side out of the system is only radiative, as is effectively the case in a vacuum enclosed design as disclosed herein, the maximum work density extracted by the Carnot engine from the setup in which a Carnot engine is used in place of the TEG or emitter of FIG. 1B is:

$${p}_{ma x}^{Carnot} = {max}_{{T}_{c}^{Carnot}} [ ( \frac{{T}_{amb}}{{T}_{c}^{Carnot}} - 1 ) Δ {p}_{r} ( {T}_{c} ) ] , \qquad ( Eq . 6 )$$

where Δpᵣ T_{c} are defined as in Eq. 4. For efficient heat flow to the hot side (hₕ=10² W/m²K as in an optimal example design as discussed herein), Tₕ of the Carnot engine can be safely approximated by T_{amb}. The value ole may be optimized in order to maximize Eq. 6. The corresponding optimal emissivity spectrum at 300 K ambient temperature may be similar but not equal to spectro-angular selectivity to the TEG spectrum of FIG. 3A as the temperature of the emitter here is lower compared to realistic devices such as TEG.

The thermodynamic limit of power extraction between the optimal emitter and that of the blackbody emitter adopted in the above-cited article entitled, “Generating light from darkness” and the window emitter proposed in Reference #16 of the above-noted U.S. Provisional application may also be compared, for the window emitter the unity emissivity is set within the wavelength range from 8 to 13 μm and zero otherwise (as previously studied and reported). In evaluating the power generation limit for a range of ambient temperatures from 245 K to 315 K, in all three cases, the generated power density limit increases as a function of ambient temperature. Using the optimal emitter results in the highest power density limit. To explain the different performance of these three emitters (Blackbody, Window and Optimal), it is noted that the optimal emitter achieves the lowest cooler temperature (T_{c}). At 300 K ambient temperature, the Carnot engine power density generation pₘₐₓ^{Carnot} is 6.4 W/m² with T_{c}=262.12 K.

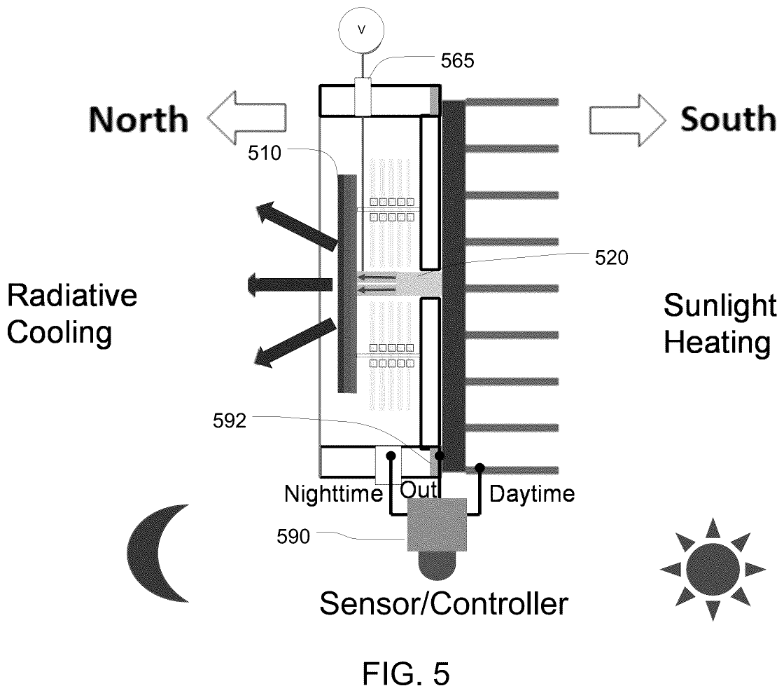

FIG. 5 is yet is another electrical-power-generator apparatus (device or system) with application-specific or environment-specific aspects according to examples of the present disclosure. Using a type of engineered or optimized apparatus as shown in any of FIG. 1A, FIG. 2 or FIG. 4A, the device or system of FIG. 5 may be designed and arranged as a day and night (e.g., 24-hour) power source. With the cold and hot sides respectively oriented on opposing sides to the left and right of the apparatus, whether during the day time or the night time, a difference in temperature between the cold and hot sides causes the (multi-layer) TEG 510, in conjunction with the spectro-angular emitter 520, to generate electrical power via an electrical terminal 565 connected to the TEG 510 by a conductor so as to provide a voltage source (V) to another circuit. A largely self-sufficient apparatus, the generated electrical power may also be provided to a sensor and/or a controller which may include logic/processor circuitries to discern and control operational aspects of the apparatus of FIG. 5 such as (but not limited to) providing: positional control of the apparatus (e.g., using a rotating motor secured to the apparatus and optionally solar powered via the same and/or a different apparatus) to move or rotate in order to track the sunlight and/or darkness; sensing the geo-location of the apparatus (e.g., using GPS-enabled signal receiver circuitry) so as to discern and optimize positioning of the apparatus relative to the angular movement of the atmospheric radiative source (e.g., sun, moon, etc.); and/or alarm/alert notifications of problems, irregularities and/or anomalies associated with the apparatus and/or its arranged position relative to aspects of the atmosphere (e.g., the atmospheric radiative source or daylight).

In this particular example illustration of FIG. 5, a sensor-controller circuit 590 (e.g., including a logic circuit and/or microcomputer) is shown connected to a lower portion of a conductor 592 which also feeds the terminal 565 to provide power to the circuit 590 which may be stored and accumulated by the circuit 590, and/or also to provide an indication to the controller part of the circuit 590 whether and an extent of which power is being generated. The extent of which power is being generated may be performed by auditory or visual signaling such as an LED emitting a flashing light according to pre-programmed levels controlled by the circuit 590. Notifications from the circuit 590 (whether remote signaling from a logic circuit in the circuit 590 and/or the sensor including a light emitting diode being controlled to flash) may be provided by an internal (not shown) logic signal feeding the circuit 590 as picked up from current flowing via the TEG 520.

Accordingly and in connection with such non-limited experimental embodiments, optimal achievable designs of nighttime thermoelectric power generation are shown with power density in the range of Watts/m² being achievable with current technologies and with improvements in power generation performance being enabled by a spectro-angular-selective emitter. Further, by considering an optimized power generation system with aspects as disclosed herein (e.g., optimal emitters at different thermal convection conditions and TEG parameters), performance close to that of the thermodynamic limit set by the Carnot heat engine may be achieved in such manners and levels as approaching harvesting electrical power at night.

It will be appreciated that such methodology, systems, features and/or aspects, in accordance with present disclosure, may be carried out for thermoelectric power generation with or without use of blackbody emission. In many applications, however, such thermoelectric power generation in accordance with present disclosure does not necessarily rely on blackbody emission at all and in other examples of the present disclosure, such thermoelectric power generation relies on blackbody emission partly or primarily.

Via such above-characterized examples, the Specification describes and/or illustrates aspects useful for implementing the claimed disclosure by way of various circuits or circuitry which may be illustrated as or using terms such as blocks, modules, device, system, unit, controller, semiconductor materials, material layers, and/or other circuit-type depictions (e.g., as in FIG. 1 of Appendix A of the underlying U.S. provisional application depict a block/module as described herein). Such circuits or circuitry are used together with other elements to exemplify how certain embodiments may be carried out in the form or structures, steps, functions, operations, activities, etc. For example, in certain of the above-discussed embodiments, one or more modules are discrete logic circuits or programmable logic circuits configured and arranged for implementing these operations/activities, as may be carried out in the approaches discussed herein.

In non-limiting experimental and/or proof-of-concept examples, aspects of the present disclosure are directed to and may be used as a systematic optimization of nighttime thermoelectric power generation systems utilizing radiative cooling, with evidence that an electrical power density over 2 W/m2, two orders of magnitude higher than the previously reported experimental result, is achievable using existing technologies. This system combines radiative cooling and thermoelectric power generation and operates at night when solar energy harvesting is unavailable. The thermoelectric power generator (TEG) itself covers less than 1 percent of the system footprint area when achieving this optimal power generation, showing economic feasibility. This disclosure also discusses the influence of emissivity spectra, thermal convection, thermoelectric figure of merit and the area ratio between the TEG and the radiative cooler on the power generation performance. In certain examples, there is optimization of the thermal radiation emitter attached to the cold side and with examples of practical material implementation. The importance of the optimal emitter is elucidated by the gain of 153% in power density compared to regular blackbody emitters.

Accordingly, different types of processes and systems (including devices) using such above disclosed aspects may be used to advantage nighttime electrical power generation. Such processes and systems include the above aspects and examples as well as others such as in the related examples and applications described in connection with the above-identified U.S. Provisional application and its accompanying Appendices A and B including the references as cited in Appendix A.

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the Appendices of the above-referenced Provisional.

The skilled artisan would recognize various terminology as used in the present disclosure by way of their plain meaning. As examples, the Specification may describe and/or illustrates aspects useful for implementing the examples by way of various semiconductor materials/circuits which may be illustrated as or using terms such as layers, blocks, modules, device, system, unit, controller, and/or other circuit-type depictions. Also, in connection with such descriptions, the term “source” may refer to source and/or drain interchangeably in the case of a transistor structure. Such semiconductor and/or semiconductive (semiconductor) materials (including portions of such structure) and circuit elements and/or related circuitry may be used together with other elements to exemplify how certain examples may be carried out in the form or structures, steps, functions, operations, activities, etc. It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

Based upon the above disclosure, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

1.-3. (canceled)

4. An apparatus comprising:
a spectro-angular selective emitter which is directed to or facing an atmosphere characterized by an absence of solar light; and
a thermoelectric power generator (TEG) having a hot side and a cold side, the cold side being coupled to the spectro-angular selective emitter, and the TEG being configured to couple heat via the hot side for generating power based on energy from the spectro-angular selective emitter, wherein the power is to be generated in response to angular selective operation of the spectro-angular selective emitter to account for angle-dependent spectral emissivity of the atmosphere.

5. The apparatus of claim 4, wherein the spectro-angular selective emitter is characterized by its ability to control or limit absorption of heat power at frequencies and angles of atmospheric transmittance and, in response to the ability to control or limit its ability to absorb heat power at frequencies and angles of atmospheric transmittance, one or more levels of the power to be generated are influenced by the angle-dependent spectral emissivity of the atmosphere.

6. The apparatus of claim 4, wherein the spectro-angular selective emitter is characterized by its ability to control or limit absorption of heat power at one or more angles including at least one incident angular range of atmospheric transmittance where emission of the atmosphere is dominant.

7. The apparatus of claim 4, wherein the spectro-angular selective emitter is characterized by its ability to control or limit absorption of heat power as a function of at least one incident angular range of atmospheric transmittance.

8. The apparatus of claim 4, wherein the spectro-angular selective emitter is angularly selective to prevent emissions at one or more large incident angular ranges of atmospheric transmittance.

9. The apparatus of claim 4, wherein the atmospheric angle-dependent spectral emissivity is a function of the atmospheric transmittance in the zenith direction.

10. The apparatus of claim 4, wherein the TEG and the spectro-angular selective emitter are part of a radiative cooler that is to radiate out power (p^{rad}) by absorbing power (p^{atm}) in the cold side stemming from the atmosphere radiation, and each of the power p^{rad} and the power p^{atm} is a function of a surface area of the cold side.

11. The apparatus of claim 4, further including an external circuit to draw power from the TEG, wherein the TEG and the spectro-angular selective emitter are part of a radiative cooler that is to radiate out power (p^{rad}) towards the external circuit by absorbing power (p^{atm}) in the cold side stemming from limited or controlled angular direction of the atmospheric transmittance, and each of the power p^{rad} and the power p^{atm} is a function of a surface area of the cold side.

12. The apparatus of claim 4, wherein the TEG and the spectro-angular selective emitter are part of a radiative cooler that is to radiate out power (p^{rad}) by accounting for angle-dependent spectral emissivity of the atmosphere and by absorbing power (p^{atm}) in the cold side stemming from the atmosphere radiation, and each of the power p^{rad} and the power p^{atm} is a function of a surface area of the cold side.

13. The apparatus of claim 4, wherein the TEG and the spectro-angular selective emitter are part of a radiative cooler that is to radiate out power (p^{rad}) by accounting for angle-dependent spectral emissivity of the atmosphere and by absorbing power (p^{atm}) in the cold side stemming from the atmosphere radiation, wherein each of the power p^{rad} and the power p^{atm} is a function of a surface area of the cold side, and the atmospheric angle-dependent spectral emissivity is a function of the atmospheric transmittance in the zenith direction.

14. The apparatus of claim 4, wherein the spectro-angular selective emitter includes a multi-layer structure that is configured to operative selectively on wavelength and incident angle, relative to the zenith direction, to facilitate thermoelectric power generation.

15. The apparatus of claim 4, wherein the spectro-angular selective emitter includes a multi-layer structure configured to operate via an emissivity spectrum, which is selective in terms of atmosphere radiation wavelength and incident angle of atmosphere radiation, that facilitates or optimizes thermoelectric power generation.

16. The apparatus of claim 4, wherein the TEG and the spectro-angular selective emitter are part of a radiative cooler that is to radiate out power as a function of: control of emissivity of the cold side based on selective atmosphere radiation wavelength and selective incident angle of atmosphere radiation; parasitic-heat-transfer control; and temperature control of the cold side.

17. The apparatus of claim 4, wherein the spectro-angular selective emitter is part of a radiative cooler that is spectrally selective to facilitate emission at frequencies wherein the radiative cooler is in an environment in which at least one of the following is applicable: atmospheric absorption is in a wavelength range of 8-13 microns; and ozone layer reflection is less than approximately 9.5 microns.

18. The apparatus of claim 4, wherein the spectro-angular selective emitter has one or more dielectric material layers and is part of a radiative cooler having an infrared window between the atmosphere and the spectro-angular selective emitter and having a vacuum chamber around the spectro-angular selective emitter; and at the hot side of the TEG, a heat sink is thermally coupled to the one or more dielectric material layers which, in operation, manifests an emissivity that approximates an optimal emissivity spectrum.

19. The apparatus of claim 4, wherein the spectro-angular selective emitter is part of a radiative cooler and said generating power includes generating power at a level that exceeds 1.5 W/m² due at least in part to at least two of: engineered environmental convection of the TEG and the spectro-angular selective emitter; a thermoelectric figure of merit set to improve nighttime power density generation or set to an upper limit of nighttime power density; and an area ratio between the TEG and the radiative cooler engineered or optimized to facilitate said generating power at a level that exceeds 1.5 W/m².

20. The apparatus of claim 4, wherein the spectro-angular selective emitter includes a plurality of dielectric material layers having respective material compositions from among Al2O3, HfO2, MgF2, SiC, SiN, SiO2, TiO2, Ta2O5, Si, and Si3N4, at least two different layer thicknesses being less than 1.0 micron, and an emissivity that approximates an optimal emissivity spectrum corresponding to the spectro-angular selective emitter.

21. The apparatus of claim 4, wherein the TEG is to generate power based on energy directed from the spectro-angular selective emitter and by controlling or limiting: ability of the spectro-angular selective emitter to absorb heat power at one or more of frequencies and angles, where emission of the atmosphere is dominant; and parasitic heat loss associated with transfer of heat into the cold side.

22. A method comprising:
for radiative cooling, using a spectro-angular selective emitter cooperatively configured with a thermoelectric power generator (TEG) that is directed to or facing an atmosphere characterized by an absence of solar light, wherein the TEG has a hot side and a cold side coupled to the spectro-angular selective emitter; and
causing the TEG to couple heat via the hot side for generating power, in response to the spectro-angular selective emitter operating as a function of atmospheric angle-dependent spectral emissivity, based on energy from the spectro-angular selective emitter.

23. The method of claim 22, wherein the spectro-angular selective emitter: includes one or more materials configured to facilitate maximum radiative cooling; and is selective in terms of incident angle, relative to atmospheric transmittance in the zenith direction, for favoring thermoelectric power generation.
